(19) United States
(12) Patent Application Publication
(10) Pub. No.: US 2006/0181884 A1
(43) Pub. Date: Aug. 17, 2006

(54) Interchangeable LED bulb and light string assembly therewith

(76) Inventor: Mingzhu Li, Vancouver (CA)

Correspondence Address: Mingzhu Li, 11 E King Edward Ave., Vancouver, BC, V5V 2B8, CA

(21) Appl. No.: 11/059,668

(22) Filed: Feb. 17, 2005

(51) Int. Cl. H01L 33/00; F21V 29/00

(52) U.S. Cl. 362/373; 313/512

(57) ABSTRACT

There is disclosed a type of interchangeable LED (light emitting diode) bulb as well as methods for making the said type of interchangeable LED bulb. A resistor is connected in series to an LED to form an interchangeable LED bulb. Two interchangeable LED bulbs are coupled in parallel and with the same polarity to form a light module. The reliability of light module is improved as a result of parallel configuration; flexibility of light module is also improved in terms of bulb replacement and color change. When two LED bulbs with different electrical characteristics are coupled in parallel to assemble a light module, the resistors can compensate the forward voltage difference of the two LEDs, LED bulbs of different color can thus be changed with each other. A light string by connecting such light modules in series and methods for making the said light string are also disclosed herein.

### BACKGROUND OF THE INVENTION

1. Field of the Invention

This invention relates to a type of interchangeable LED bulb, and to a light module assembled by connecting two interchangeable LED bulbs in parallel and with the same polarity, and further to a light string assembled by connecting such light modules together in series.

2. Description of the Related Art

LEDs have increasingly been used as luminance sources in various applications. In addition to other desirable features, availability in a variety of colors makes LEDs very attractive and suitable for decoration purposes. As a result, one application where LEDs become particularly popular in recent years is decorative light strings. Such light strings are usually formed from a plurality of LEDs connected in series, where the LEDs may have different colors.

The disadvantage of such series configuration is that, the whole light string will turn dark if one of the LEDs in the string burns open or is somehow disconnected from the string; and it's a time consuming task to find out the faulty one among all LEDs on the string. That is why LED strings currently available in the market have LED bulbs molded together with the lampholders and it is thus impossible to replace any bulbs without cutting off electrical wires. As a result, the whole string will usually be thrown away if one failing LED causes the string to become dark.

In another configuration of forming a light module, two LEDs are connected in parallel and with the same polarity, but with no other electrical elements; similar light modules are then connected in series to form a light string. Reliability of the light string is improved, as with the parallel configuration, when one light bulb burns open, the other bulb in parallel will still keep current flowing through the string, provided that it has the capacity of conducting all current flowing through a light module. Only the faulty bulb will become dark and all other bulbs in the string will stay lit, so it's easy to identify the failing bulb and replace it.

A disadvantage of this configuration is lack of flexibility for free color change with a light string. We know LEDs made of different semiconductor materials have different ranges of emitted light wavelength and different electrical characteristics. When two LEDs of different colors are connected in parallel and with the same polarity, but with no other electrical elements, the one with a lower threshold forward voltage will conduct current first and usually will take more current than the other one that has a higher threshold forward voltage. In an extreme case, one LED conducts all current while the other one has no current flowing through it. It is unacceptable that some light bulbs are illuminating while others are dark in a light string. Therefore, typically two substantially similar LEDs, which have the same electrical characteristics, and usually have the same color, must be selected for the parallel connection to form a light module, otherwise, normal illumination can not be ensured for every bulb. As a result, an LED bulb of one color can not replace an LED bulb of another color; an LED bulb can only replace an LED bulb of the same color. Therefore, in this configuration, as light modules in a light string always have two LED bulb of a same color, free color combination for a light string is not possible.

Accordingly, interchangeable LED bulbs and a light module therewith are provided in the present invention to ensure the light string formed from such interchangeable bulbs and light modules are not only reliable in terms of illumination, but also flexible in terms of free color change and combination.

### SUMMARY OF THE INVENTION

According to one aspect of the present invention, there is provided a type of interchangeable LED bulb, and a method for making such type of interchangeable LED bulb, where a resistor is connected in series with an LED. A resistor is connected in series immediately to either anode or cathode pin of an LED to form the said interchangeable LED bulb.

According to another aspect of the present invention, there is provided a light module, where two interchangeable LED bulbs are connected together in parallel and with the same polarity. At least one of the two interchangeable LEDs may have a maximum current rating sufficient to carry all current conducted through the light module.

According to yet another aspect of the present invention, a plurality of such light modules is connected together in series to provide a string of such light modules. The number of light modules that are connected together in series would be selected such that the sum of the minimum operating voltage for each of the light module is less than the voltage available to supply the string. For example, the minimum operating voltage of a light module may be the greater of the minimum operating voltage of the two LEDs.

According to another aspect of the present invention, a resistor should be selected such that the current flow through the LED in an interchangeable LED bulb is less than the maximum current of the LED. Usually a resistor must be selected based on both LED electrical characteristics and the number of light modules connected in a light string, so that nominated current will flow through the LED bulb. The actual power consumption of a resistor must be less than its maximum power consumption.

According to another aspect of the present invention, the light string as a whole also includes a way of limiting the current flowing through the light modules, for example a resistor connected in series with the light string.

According to another aspect of the present invention, a rectifier is used to convert an AC supply voltage into a DC voltage for driving a light string.

### BRIEF DESCRIPTION OF THE DRAWINGS

FIG. 1A and FIG. 1B show a schematic diagram of an interchangeable LED bulb according to a first embodiment of the present invention.

FIG. 2A and FIG. 2B show an illustrative diagram of an interchangeable LED package according to a second embodiment of the present invention.

FIG. 3A and FIG. 3B show an illustrative diagram of an interchangeable LED package according to a third embodiment of the present invention.

FIG. 4 is a schematic diagram of a light module according to a fourth embodiment of the present invention.

FIG. 5 is a schematic diagram of a light string according to a fifth embodiment of the present invention.

FIG. 6 is a schematic diagram of a light string according to a sixth embodiment of the present invention.

FIG. 7 is a schematic diagram of a light string according to a seventh embodiment of the present invention.

FIG. 8 is a diagram of current-versus-voltage characteristics of two different LEDs.

### DETAILED DESCRIPTION OF THE INVENTION

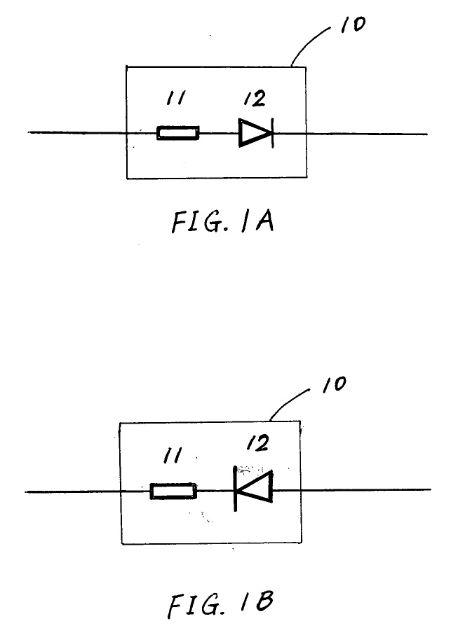

FIG. 1A shows the schematic diagram of an interchangeable LED bulb according to a first embodiment of the present invention, illustrated as 10. The interchangeable LED bulb 10 includes a resistor 11 and an LED bulb 12. Resistor 11 is electrically connected in series with LED bulb 12 and is connected immediately to the anode pin of the LED bulb 12.

FIG. 1B shows the schematic diagram of an interchangeable LED bulb according to the first embodiment of the present invention, illustrated as 10. The interchangeable LED bulb 10 includes a resistor 11 and an LED bulb 12. Resistor 11 is electrically connected in series with LED bulb 12 and is immediately connected to the cathode pin of LED bulb 12.

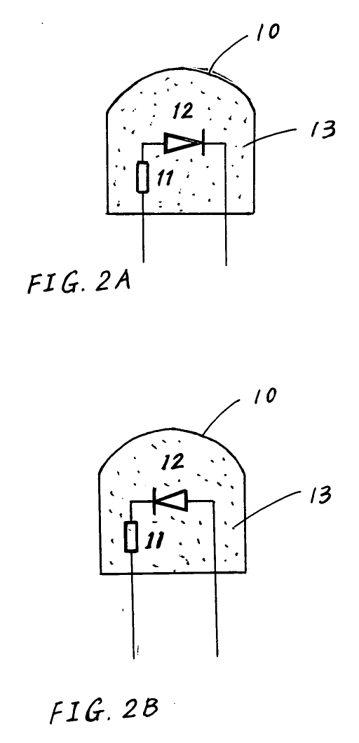

FIG. 2 shows an interchangeable LED bulb according to a second embodiment of the invention, where resistor 11 and LED bulb 12 are packed and sealed together within a transparent LED seal body 13 as represented by the shadow body, and thus making a type of integral interchangeable LED bulb 10. The resistor 11 is electrically connected in series to LED bulb 12, being connected immediately to either anode pin or cathode pin of the LED bulb 12, respectively shown in FIG. 2A and FIG. 2B.

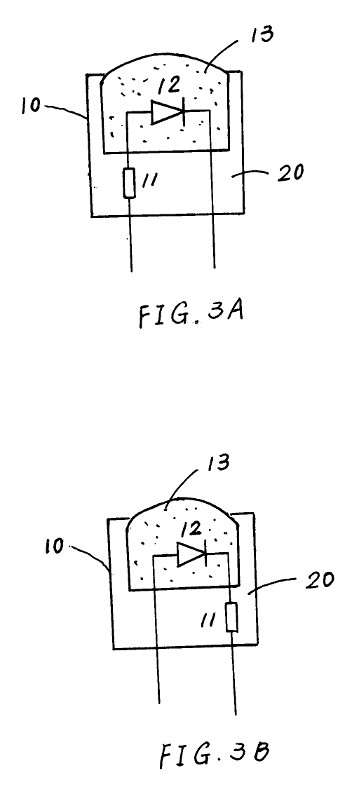

FIG. 3A and FIG. 3B show an interchangeable LED bulb 10 according to a fourth embodiment of the present invention, where the resistor 11 is electrically connected in series to LED bulb 12, and is connected immediately to either anode pin or cathode pin of the LED bulb 12 respectively. LED bulb 12 is packed and sealed alone within the LED transparent seal body 13 as represented by the shadow body, and resistor 11 and LED bulb 12 are then installed and secured in a common holder 20, thus making a second type of integral interchangeable LED bulb 10.

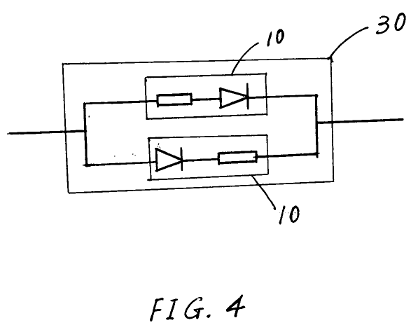

FIG. 4 is a schematic diagram of a light module according to a fourth embodiment of the present invention, illustrated as 30. The light module 30 includes a first interchangeable LED bulb 10 electrically connected to a second interchangeable LED bulb 10 in parallel and with the same polarity. It is desirable that each of two interchangeable LED bulbs has a rated forward current greater than the maximum total current expected to flow through light module 30. So that, when one LED bulb burns open, the other one will carry the total current and thus keep the rest LED bulbs in the string stay lit.

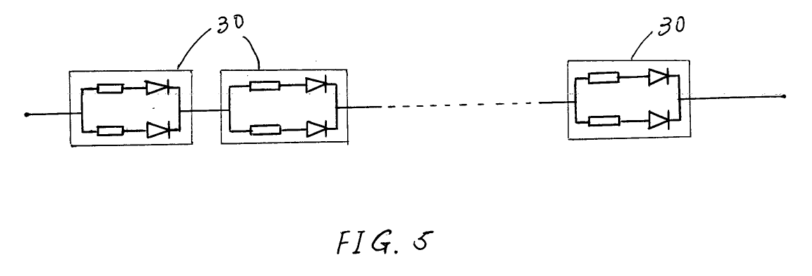

FIG. 5 is a schematic diagram of a light string according to a fifth embodiment of the present invention, where a plurality of light modules 30 are electrically connected in series and with the same polarity to form a light string.

As shown in FIG. 4, in the light module 30, the first LED bulb may have a different color than the second LED bulb, and their characteristics are thus different. Because LEDs of different colors are made of different semiconductor materials, they have different electrical characteristics.

The resistor in each interchangeable LED bulb must be selected correctly. So that the interchangeable LED bulb will work safely and properly when it is coupled together in parallel with a second interchangeable LED bulb to form a light module, and when that module is connected with other light modules to form a light string as shown in FIG. 5.

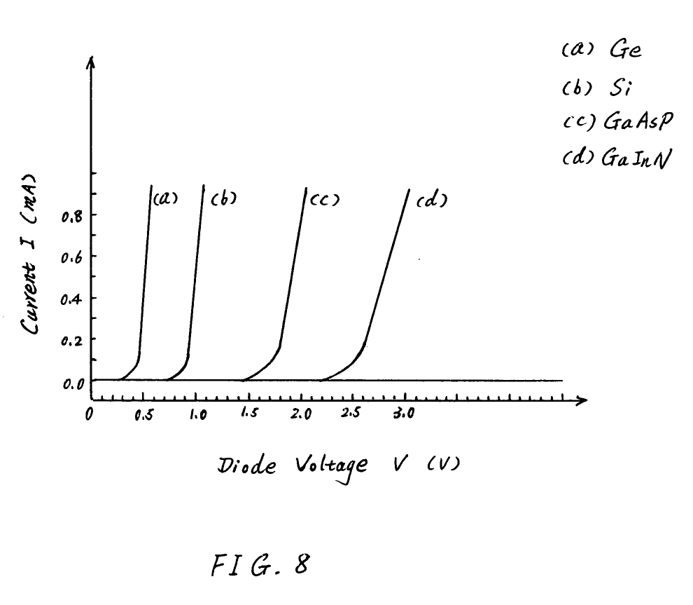

FIG. 8 shows the electrical characteristics of four types of LEDs with different colors. Take curves (a) and (d) for example, as shown in FIG. 8, the LED of curve (a) has a lower threshold forward voltage, and must be connected to a resistor with an impedance greater than the resistor connected to the LED with curve (d) that has greater threshold forward voltage. Otherwise, there may arise an undesired situation such that, the LED of lower threshold forward voltage already illuminates fully and its current flow is near its maximum current limit, while the LED of greater threshold voltage does not get enough voltage to illuminate and is still dark. To avoid such undesirable situation, a resistor's impedance value must be selected based on both the LED characteristics and the number of light module used in a light string, the selection of resistor will be further explained in the following paragraphs.

Firstly, from manufacturing point of view, the number of light module in a light string must be determined first. There can be any number of light modules in a light string, as long as the sum of the minimum operating voltage for each of the light module is less than the supply voltage available for driving the light string.

Secondly, when a resistor is selected for an LED and a light string, the actual power consumption of the resistor must be less than the maximum power consumption of the resistor, and the current flow through the LED must be less than its maximum current.

Thirdly, suppose there is no extra resistor or other current limiting element connected in a light string, only interchangeable LED bulbs are assembled in pairs to form light modules, and light modules are assembled in series to form a light string. In this case, the resistor in series with a certain LED should be selected by the following Equation (1):
R=(V_{supply}÷N_{module}−V_{lednominal})÷I_{lednominal} (1),

where: R is the impedance value of the resistor,

V_{supply} is the supply voltage,

N_{module} is the number of light module,

V_{lednominal} is the nominated operating voltage of LED,

I_{lednominal} is the nominated operating current of LED.

The impedance of a resistor depends on the number of light modules used in a light string, as indicated by the first term of Equation (1). And the impedance of a resistor for an LED must also be based on the current and voltage parameters of the LED to which the resistor is connected to in series, as indicated by the second and third terms of Equation (1). An LED bulb will work with its nominated operating current at its nominated operating voltage, and thus safe operation is ensured for the LED, if the resistor connected to the LED bulb is selected according to Equation (1).

Since an interchangeable LED bulb includes a resistor related to the number of light module in a light string, the interchangeable LED bulb can only be used in a light string with the same number of light modules for which the resistor is selected.

All interchangeable LED bulbs of different characteristics can replace each other as long as they are assembled for the same number of light modules of a light string. And only those assembled for the same number of light modules of a light string can replace each other. Because only in that case, the resistors can compensate correctly for the forward voltage difference of the two LEDs that have different color and different characteristics when they are coupled together in parallel. Otherwise, a misplaced interchangeable LED bulb may not work at its nominated operating point; as a result, it may not work properly, and may cause other LED bulbs not to work properly, or even cause damage to itself or other LED bulbs.

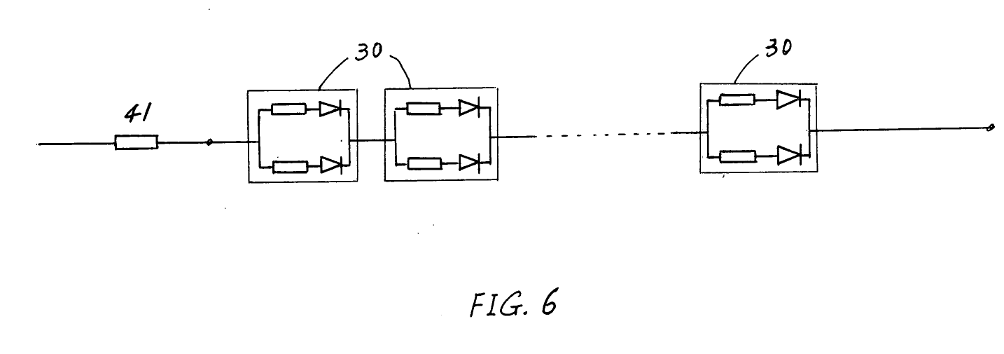

FIG. 6 shows a schematic diagram of a light string based on a sixth embodiment of the present invention. As shown in FIG. 6, a resistor R_{g}, as indicated as 41, is electrically connected in series with a light string to limit the current flow through the light modules in the light string. The general principle for selecting R_{g} and the resistors for each interchangeable LED bulb is that, the actual power consumption of all resistors must be less than their respective maximum power consumption, and the current flow through each LED must be less than its maximum current flow. Furthermore, the sum of the minimum operating voltage for each of the light module is less than the supply voltage available for driving the light string.

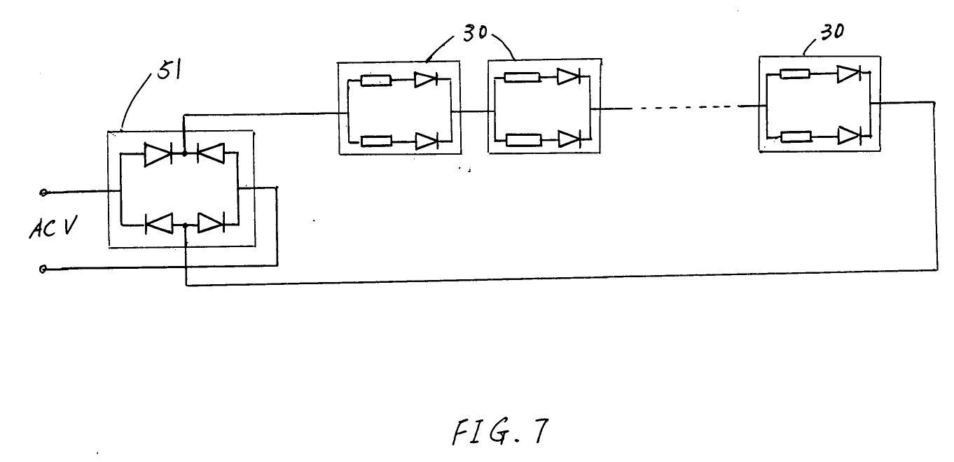

FIG. 7 shows a schematic circuitry diagram of a light string based on a seventh embodiment of the present invention. As shown in FIG. 7, a rectifier 51 is added to a light string. The rectifier 51 rectifies an AC supply voltage into a DC voltage and then drives the light string.

It would be understood by those skilled in the art that changes, modifications and substitutions can be made to the mentioned embodiments without departing from the principle and scope of the present invention expressed in the claims made herein. For example, although the invention has been discussed in terms of light emitting diodes, those skilled in the art may recognize that similar benefits could be achieved by substituting other similar polarized photon-emitting semiconductor devices, such as light emitting transistors.

While the invention has been described as having particular application for light string, those skilled in the art will recognize it has wider application, for example in automotive lighting devices.

What is claimed is:

1. An interchangeable LED bulb, comprising:
a light emitting diode (“LED”), and
a resistor being connected to the LED in series.

2. An interchangeable LED bulb as claimed in claim 1, wherein the resistor connected in series to the LED is connected immediately to the anode pin of the LED.

3. An interchangeable LED bulb as claimed in claim 2, wherein the LED and the resistor are sealed together in a transparent seal body.

4. An interchangeable LED bulb as claimed in claim 2, wherein the LED is sealed alone in a transparent seal body; the resistor and the LED are placed and secured in a common housing body.

5. An interchangeable LED bulb as claimed in claim 1, wherein the resistor connected in series to the LED is connected immediately to the cathode pin of the LED.

6. An interchangeable LED bulb as claimed in claim 5, wherein the LED and the resistor are sealed together in a transparent seal body.

7. An interchangeable LED bulb as claimed in claim 5, wherein the LED is sealed alone in a transparent seal body; the resistor and the LED are placed and secured in a common housing body.

8. An interchangeable LED bulb as claimed in claim 1, further comprising a heat sink thermally connected to the LED, or the resistor, or both the LED bulb and the resistor.

9. An interchangeable LED bulb as claimed in claim 1, further comprising a light diffuser covering the LED bulb.

10. A light module, comprising:
a first interchangeable LED bulb as defined in claim 1,
a second interchangeable LED bulb as defined in claim 1,
wherein the first interchangeable LED bulb is connected to the second interchangeable LED bulb in parallel and with the same polarity.

11. A light module as claimed in claim 10, wherein at least one of the first and the second interchangeable LED bulbs have a maximum current rating sufficient to carry all current conducted through the light module.

12. A light module as claimed in claim 11, wherein the minimum operating voltage of the light module is the greater of the minimum operating voltage of the first interchangeable LED bulb and the minimum operating voltage of the second interchangeable LED bulb.

13. A light string, comprising:
a plurality of light module as defined in claim 12, being connected with each other in series and with the same polarity.

14. A light string as claimed in claim 13, wherein the number of light modules that are connected in series is selected such that, the sum of the minimum operating voltage for each of the light modules is less than the supply voltage available to drive the light string.

15. A light string as claimed in claim 13, further comprising means for limiting the current flowing through the light modules.

16. A light string as claimed in claim 15, wherein the means for limiting current comprises a resistor connected in series with a light module.

17. A light string as claimed in claim 13, further comprising a rectifier. The said rectifier rectifies an AC supply voltage into a DC voltage for driving the light string.
